(19) United States
(12) Patent Application Publication
(10) Pub. No.: US 2005/0128834 A1
(43) Pub. Date: Jun. 16, 2005

(54) Data transfer circuit having collision detection circuit

(75) Inventor: Noriaki Shinagawa, Tokyo (JP)

Correspondence Address: NIXON PEABODY, LLP, 401 9TH STREET, NW, SUITE 900, WASHINGTON, DC, 20004-2128, US

(73) Assignee: Oki Electric Industry Co., Ltd., Tokyo (JP)

(21) Appl. No.: 11/008,120

(22) Filed: Dec. 10, 2004

(30) Foreign Application Priority Data
Dec. 12, 2003 (JP) 2003-414860

(51) Int. Cl. G11C 7/00

(52) U.S. Cl. 365/201

(57) ABSTRACT

A data transfer circuit includes a buffer, a counter and first and second collision circuits. The buffer stores write data in response to a write control signal and reads out data in response to a read control signal. The counter counts a number of data stored in the buffer and outputs a count value representing a number of the count. The first collision detection circuit is connected to the counter. The first collision detection circuit outputs the count value when the read control signal is in an inactive state and outputs a write prohibit signal when the read control signal is in an active state. The second collision detection circuit is connected to the counter. The second collision circuit outputs the count value when the write control signal is in an inactive state and outputs a read prohibit signal when the write control signal is in an active state.

### BACKGROUND OF THE INVENTION

The present invention relates to a data transfer circuit that performs data transfer through the use of a FIFO (First-In First-Out) buffer.

A conventional data transfer circuit using a FIFO buffer is built in, for example, a data communication card for transferring data between a PHS (Personal Handy phone System) and a notebook-size personal computer (hereinafter called “personal computer”).

A data transfer circuit transfers data from a PHS to a personal computer, for example, and includes a FIFO memory, a counter, a buffer and a selector.

The FIFO memory sequentially stores write data in accordance with a write control signal, reads the old data in order in accordance with a read control signal, and outputs the same as read data. The counter outputs the number of data stored in the FIFO memory as a count value and is configured of an up-down counter. The counter increases the count value in response to the write control signal and decreases the count value in response to the read control signal.

The buffer outputs the count value outputted from the counter as a count value in accordance with a state read signal. The selector selects the read data of the FIFO memory or the count value of the counter in accordance with a state read signal and outputs the same as data.

When data to be transferred from the PHS side to the personal computer side is generated, such a data transfer circuit reads the count value of the counter in accordance with the state read signal on the PHS side, confirms the number of writable data and thereafter writes write data into the FIFO memory. On the other hand, the data transfer circuit periodically reads the count value of the counter in accordance with the state read signal on the personal computer side, confirms the number of readable data and thereafter reads the data retained in the FIFO memory. Thus, the transfer of asynchronous data from the PHS side to the personal computer side is performed.

However, the data transfer circuit is accompanied by a problem that when the count value of the counter is read from the personal computer side where write data is being written from the PHS side to the FIFO memory, an invalid count value is read and hence read data larger than the number of actually stored data are read. Similarly, a problem arises in that when the count value of the counter is read from the PHS side where read data is being read from the FIFO memory on the personal computer side, an invalid count value is read and hence write data exceeding a free or empty space is written into the FIFO memory.

### SUMMARY OF THE INVENTION

It is an object of the present invention to provide a data transfer circuit capable of preventing a malfunction of data transfer due to an invalid count value CNT and carrying out reliable data transfer.

A data transfer circuit of the present invention includes a buffer, a counter and first and second collision circuits. The buffer stores write data in response to a write control signal and reads out data in response to a read control signal. The counter counts a number of data stored in the buffer and outputs a count value representing a number of the count. The first collision detection circuit is connected to the counter. The first collision detection circuit outputs the count value when the read control signal is in an inactive state and outputs a write prohibit signal when the read control signal is in an active state. The second collision detection circuit is connected to the counter. The second collision circuit outputs the count value when the write control signal is in an inactive state and outputs a read prohibit signal when the write control signal is in an active state.

### BRIEF DESCRIPTION OF THE DRAWINGS

FIG. 1 is a configurational diagram of a data transfer circuit showing an embodiment of the present invention; and

FIG. 2 is a signal waveform diagram illustrating one example of the operation of a collision detection circuit 20 shown in FIG. 1.

### DETAILED DESCRIPTION OF THE PREFERRED EMBODIMENTS

The above and other objects and novel features of the present invention will become more completely apparent from the following description of preferred embodiment when the same is read with reference to the accompanying drawings. The drawings, however, are for the purpose of illustration only and by no means limitative of the invention.

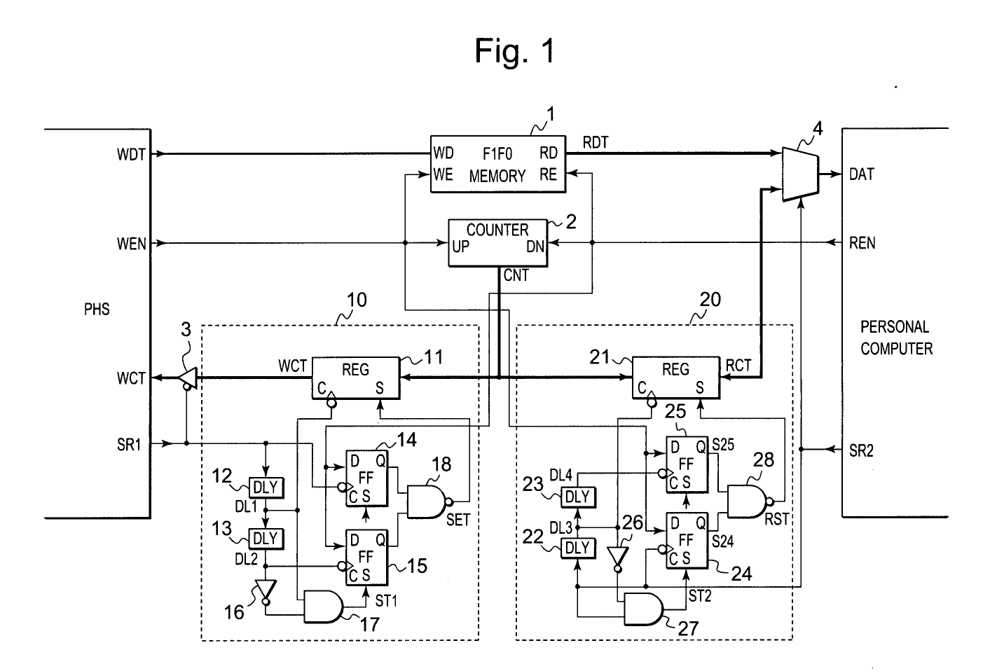

FIG. 1 is a configurational diagram of a data transfer circuit showing an embodiment of the present invention.

The data transfer circuit transfers data from a first device (e.g., PHS) connected to the left side in the drawing to a second device (e.g., personal computer) connected to the right side in the drawing, for example.

The data transfer circuit has collision detection circuits 10 and 20 in addition to an FIFO memory 1, a counter 2, a buffer 3 and a selector 4 similar to the conventional ones.

The FIFO memory 1 sequentially stores write data WDT supplied from the PHS side in accordance with a write control signal WEN, reads the old data in order in accordance with a read control signal REN supplied from the personal computer side, and outputs the so-read data as read data RDT. The counter 2 outputs the number of data stored in the FIFO memory 1 as a count value CNT and is configured of an up-down counter. When the write control signal WEN is supplied to the counter 2, the count value CNT is incremented by 1. When the read control signal REN is supplied to the counter 2, the count value CNT is decremented by 1.

The buffer 3 outputs a count value WCT controlled by the collision detection circuit 10, in accordance with a state read signal SR1 supplied from the PHS side. Further, the selector 4 selects the read data RDT of the FIFO memory 1 or a count value RCT controlled by the collision detection circuit 20, in accordance with a state read signal SR2 supplied from the personal computer side and outputs the selected one as data DAT.

The collision detection circuit 10 detects the collision of access where it intends to read the count value CNT of the counter 2 from the PHS side when the read data RDT is being read from the FIFO memory 1 on the personal computer side, for example, and output the count value WCT indicative of a full state to prohibit writing into the FIFO memory 1 from the PHS side. On the other hand, when the collision detection circuit 20 detects the collision of access where it intends to read the count value CNT of the counter 2 from the personal computer side when the write data WDT is being written into the FIFO memory 1 on the PHS side, for example, and outputs the count value RCT indicative of an empty state to prohibit reading from the FIFO memory 1 to the personal computer.

The collision detection circuit 10 includes a register (REG) 11 for holding the count value CNT outputted from the counter 2, two-stage delayers (DLY) 12 and 13 for respectively delaying the state read signal SR1 supplied from the PHS side by predetermined time, and flip-flops (hereinafter called “FFs”) 14 and 15 for respectively holding the read control signal REN supplied from the personal computer side.

The state read signal SR1 is supplied to the delayer 12 and given to a clock terminal C of the FF 14. A delay signal DL1 outputted from the delayer 12 is supplied to the input side of the delayer 13 and a clock terminal C of the register 11. A delay signal DL2 outputted from the delayer 13 is supplied to a clock terminal C of the FF 15. The delay signal DL2 is further inverted by an inverter 16, followed by being supplied to one input of a two-input AND gate (hereinafter called “AND”) 17. The other input of the AND 17 is supplied with the delay signal DL1. Then, a set signal ST1 outputted from the AND 17 is supplied to set terminals S of the FFs 14 and 15.

The FFs 14 and 15 respectively retain the read control signal REN supplied to their data terminals D with the rise timings of the delay signals DL1 and DL2 and output the same from their output terminals Q. When a set signal ST1 of a level “H” is supplied to the set terminals S of the FFs 14 and 15, the FFs 14 and 15 forcibly set the contents retained therein to “H”. The output terminals Q of the FFs 14 and 15 are connected to the inputs of a two-input negated AND gate (hereinafter called “NAND”) 18. A set signal SET outputted from the NAND 18 is supplied to a set terminal S of the register 11.

The register 11 holds the count value CNT of the counter 2 with the fall timing of the delay signal DL1 supplied to the clock terminal C. When the set terminal S of the register 11 is supplied with a set signal SET of “H”, the register 11 forcibly sets all bits of the contents retained therein to “H”. The retained contents of the register 11 is supplied to the buffer 3 as the count value WCT.

The collision detection circuit 20 includes a register 21 for holding the count value CNT outputted from the counter 2, two-stage delayers 22 and 23 for respectively delaying the state read signal SR2 supplied from the personal computer side by predetermined time, and FFs 24 and 25 for respectively holding the write control signal WEN supplied from the PHS side.

The state read signal SR2 is supplied to the delayer 22 and given to a clock terminal C of the FF 24. A delay signal DL3 outputted from the delayer 22 is supplied to the input of the delayer 23 and a clock terminal C of the register 21. A delay signal DL4 outputted from the delayer 23 is supplied to a clock terminal C of the FF 25. The delay signal DL3 is further inverted by an inverter 26, followed by being supplied to one input of a two-input AND 27. The other input of the AND 27 is supplied with the state read signal SR2. Then, a set signal ST2 outputted from the output of the AND 27 is supplied to set terminals S of the FFs 24 and 25.

The FFs 24 and 25 respectively retain the write control signal WEN supplied to their data terminals D with the fall timings of the delay signals DL3 and DL4 and output the same from their output terminals Q. When a set signal ST2 of “H” is supplied to the set terminals S of the FFs 24 and 25, the FFs 24 and 25 forcibly set the contents retained therein to “H”. The output terminals Q of the FFs 24 and 25 are connected to the inputs of a two-input NAND 28. A reset signal RST outputted from the NAND 28 is supplied to a reset terminal R of the register 21.

The register 21 holds the count value CNT of the counter 2 with the fall timing of the delay signal DL3 supplied to the clock terminal C. When the reset terminal R of the register 21 is supplied with a reset signal RST of “H”, the register 21 forcibly resets all bits retained therein to a level “L”. The retained contents of the register 21 is supplied to the selector 4 as the count value RCT.

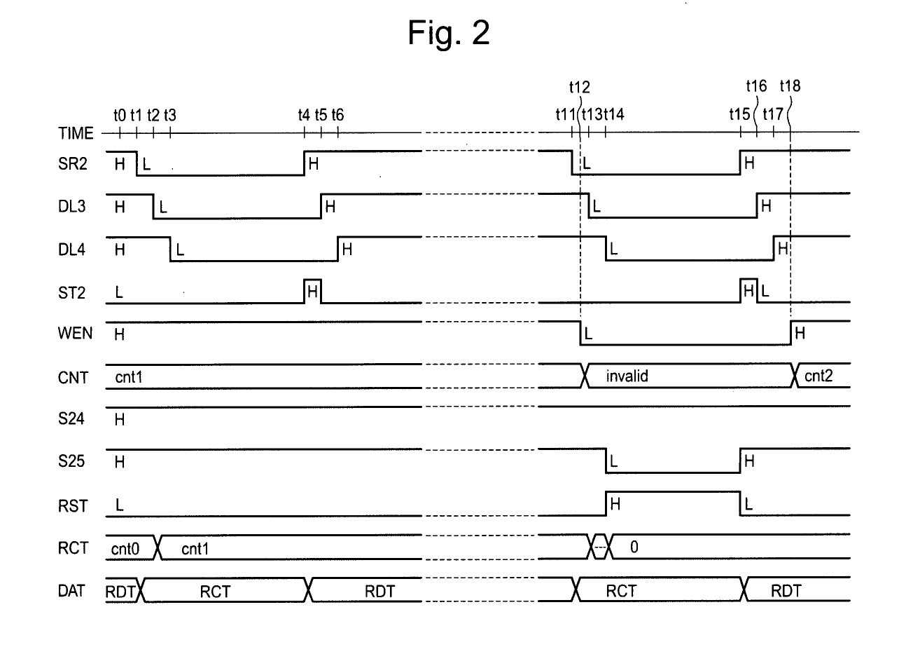

FIG. 2 is a signal waveform diagram showing one example of the operation of the collision detection circuit 20 in FIG. 1. The operation of FIG. 1 will be explained below with reference to FIG. 2.

When access is not made to the FIFO memory 1 at all at a time t0 in FIG. 2, a write control signal WEN and a state read signal SR1 outputted from the PHS side, and a read control signal REN and a state read signal SR2 outputted from the personal computer side are all “H”. A count value CNT of the counter 2 at this time is set as cnt1. Since the state read signal SR2 is of “H” continuously, delay signals DL3 and DL4 are also of “H”, and a set signal ST2 outputted from the AND 27 is of “L”. Since the FFs 24 and 25 are set in accordance with the rising edge of the state read signal SR2 as will be described later, signals S24 and S25 outputted from these FFs 24 and 25 are also “H”. Thus, a reset signal RST outputted from the NAND 28 is brought to “L”, and a count value CNT (=cnt0) of the counter 2 held in the register 21 with the previous timing is held as it is and outputted as a count value RCT.

At a time t1, the state read signal SR2 is brought to “L” to read the contents of the counter 2 from the personal computer side. If, at the time, the operation of writing data into the FIFO memory 1 is not carried out from the PHS side, then the write control signal WEN is of “H”. Since the state read signal SR2 has been brought to “L”, the register 21 side is selected by the selector 4 and hence the count value RCT outputted from the register 21 is outputted to the personal computer side as data DAT. Further, the write control signal WEN is retained in the FF 24 by the falling edge of the state read signal SR2 but the signal S24 outputted from the FF 24 remains at “H”.

When the delay time of the delayer 22 elapses at a time t2, the delay signal DL3 outputted from the delayer 22 changes from “H” to “L”. Thus, the count value (=cnt1) of the counter 2 is retained in the register 21 and outputted as data DAT through the selector 4.

When the delay time of the delayer 23 elapses at a time t3, the delay signal DL4 outputted from the delayer 23 changes from “H” to “L”. With the falling edge of the delay signal DL4, the write control signal WEN is retained in the FF 25 but the signal S25 outputted from the FF 25 remains at “H”. Accordingly, the reset signal RST outputted from the NAND 28 remains unchanged at “L”, and the count value CNT (=cnt1) of the counter 2 held in the register 21 is continuously outputted as the count value RCT.

When the state read signal SR2 is returned to “H” at a time t4, the data DAT outputted from the selector 4 is switched to read data RDT of the FIFO memory 1. On the other hand, the set signal ST2 outputted from the AND 27 becomes “H” so that the FFs 24 and 25 are set. In this case, the signals S24 and S25 outputted from the FFs 24 and 25 remain unchanged because they have already been brought to “H”.

When the delay time of the delayer 22 elapses at a time t5, the delay signal DL3 outputted from the delayer 22 changes from “L” to “H”. Thus, the set signal ST2 outputted from the AND 27 is brought to “L”.

Further, when the delay time of the delayer 23 elapses at a time t6, the delay signal DL4 outputted from the delayer 23 changes from “H” to “L”. Consequently, the collision detection circuit 20 returns to the same state as the time t0.

Thus, when accesses on the PHS side and the personal computer side do not collide with each other, the personal computer is capable of correctly reading the count value CNT of the counter 2.

Next, at a time t11, the state read signal SR2 is brought to “L” to read the contents of the counter 2 from the personal computer side. If the operation of writing data into the FIFO memory 1 is not performed from the PHS side at this time, then the write control signal WEN is of “H”. Since the state read signal SR2 has been brought to “L”, the register 21 side is selected by the selector 4 and hence the count value RCT outputted from the register 21 is outputted as data DAT. Further, the write control signal WEN is retained in the FF 24 by the falling edge of the state read signal SR2 but the signal S24 outputted from the FF 24 remains at “H”.

When the operation of writing the data from the PHS side to the FIFO memory 1 is started at a time t12, the write control signal WEN goes “L” with the start of the writing operation so that the value of the counter 2 is updated. Thus, the count value CNT of the counter 2 is brought to an invalid value.

When the delay time of the delayer 22 elapses at a time t13, the delay signal DL3 outputted from the delayer 22 changes from “H” to “L”. Thus, the count value (=invalid) of the counter 2 is retained in the register 21 and outputted as data DAT through the selector 4.

When the delay time of the delayer 23 elapses at a time t14, the delay signal DL4 outputted from the delayer 23 changes from “H” to “L”. With the falling edge of the delay signal DL4, the write control signal WEN is retained in the FF 25 and the signal SR25 outputted from the FF 25 is brought to “L”. Thus, the reset signal RST outputted from the NAND 28 goes “H” so that the contents held in the register 21 is reset, thus resulting in “0”, after which such “0” is outputted as the count value RCT. Since the read count value RCT is “0” on the personal computer side, it is judged that no data exists in the FIFO memory 1. Thus, the operation of reading data from the FIFO memory 1 is not carried out. Since, however, the count value CNT of the counter 2 is read in a predetermined cycle on the personal computer side, the correct count value is read if the collision with the PHS side is not generated with the next read timing, thereby making it possible to read the data retained in the FIFO memory 1.

When the state read signal SR2 is returned to “H” at a time t15, the data DAT outputted from the selector 4 is switched to read data RDT of the FIFO memory 1. On the other hand, the set signal ST2 outputted from the AND 27 goes “H” and the FFs 24 and 25 are set so that their signals S24 and S25 are brought to “H”.

When the delay time of the delayer 22 elapses at a time t16, the delay signal DL3 outputted from the delayer 22 changes from “L” to “H”. Thus, the set signal ST2 outputted from the AND 27 is brought to “L”.

When the delay time of the delayer 23 elapses at a time t17, the delay signal DL4 outputted from the delayer 23 changes from “H” to “L”.

Further, when the operation of writing the data from the PHS side to the FIFO memory 1 is completed at a time t18, the write control signal WEN is brought to “H” so that the count value CNT of the counter 2 is updated to reach cnt2. Thus, the data transfer circuit is returned to the same state as the time t0.

Incidentally, the operation of the collision detection circuit 10 is also substantially similar to the collision detection circuit 20. However, the collision detection circuit 10 outputs a count value WCT indicative of full space of the FIFO memory 1 to the PHS side where the read operation of the FIFO memory 1 on the personal computer side and the read operation of the counter 2 on the PHS side collide with each other.

Thus, the data transfer circuit according to the present embodiment has the collision detection circuits 10 and 20 one of which outputs the count value CNT of the counter 2 to one device (e.g., personal computer) so long as the access from the other device (e.g., PHS) to the FIFO memory 1 is not performed immediately before and after the timing provided to read the count value CNT of the counter 2 by the one device, and the other of which outputs the count value indicative of no need for reading or an inability to perform writing at times other than it. Thus, the data transfer circuit has the advantage of being capable of preventing false read and write operations from being preformed by reading an invalid count value CNT due to the collision of access.

Incidentally, the above-described embodiment is strictly for the purpose of making clear the technical contents of the present invention. The present invention is not meant to be construed in a limiting sense by being limited to the above embodiment alone. Various changes can be made to the invention within the scope described in the following claims of the present invention. Modifications of the disclosed embodiment include the following, for example.

(a) Although the data transfer circuit for performing the transfer of data from the PHS side to the personal computer side has been explained, data can be transferred from the personal computer side to the PHS side using a similar circuit.

(b) The device for performing data transfer is not limited to the PHS and the personal computer.

(c) The circuit configurations of the collision detection circuits 10 and 20 are not limited to ones illustrated in the drawing. If one capable of outputting such a count value CNT as to stop data transfer to a device intended to detect simultaneous access to the counter 2 and read the count value CNT of the counter 2 is adopted, it is then applicable in like manner.

The present invention is provided with a first collision detection circuit which outputs a value indicative of full space of an FIFO memory to a first device regardless of a count value of a counter where a state read signal for reading the count value of the counter is detected from the first device when reading of data from the FIFO memory is being performed by a second device, and a second collision detection circuit which outputs a value indicative of vacancy or free space of the FIFO memory to the second device regardless of a count value of the counter where a state read signal for reading the count value of the counter is detected from the second device when writing of data into the FIFO memory is being performed by the first device.

Thus, when the collision of access occurs, the first device determines that the FIFO memory is full in space, and hence the writing of data into the FIFO memory is suppressed. It is determined in the second device that the FIFO memory is free in space. Hence the reading of data from the FIFO memory is suppressed. Thus, the present invention brings about the advantage of being capable of preventing a malfunction of data transfer based on an invalid count value and performing reliable data transfer.

1. A data transfer circuit comprising:
a first buffer circuit storing write data in response to a write control signal and reading out data stored therein in response to a read control signal;
a counter counting a number of data stored in the first buffer circuit and outputting a count value representing a number of the count;
a first collision detection circuit connected to the counter, the first collision circuit outputting the count value when the read control signal is in an inactive state and outputting a write prohibit signal when the read control signal is in an active state; and
a second collision detection circuit connected to the counter, the second collision circuit outputting the count value when the write control signal is in an inactive state and outputting a read prohibit signal when the write control signal is in an active state.

2. A data transfer circuit according to claim 1, further comprising
a second buffer circuit connected to the first collision circuit, the second buffer circuit transferring the signal received from the first collision signal in response to a write status signal, and
a selector connected to the first buffer circuit and the second collision circuit, the selector transferring the data received from the first buffer circuit or the signal received from the second collision circuit in response to a read status signal.

3. A data transfer circuit according to claim 1, wherein the first buffer circuit is a first in first out memory.

4. A data transfer circuit according to claim 1, wherein the counter is an up-down counter having an up count input terminal connected to receive the write control signal and a down input terminal connected to receive a read control signal.

5. A data transfer circuit according to claim 1, wherein the first collision detection circuit includes
a register connected to the counter, and
a control circuit connected to the counter, the control signal outputting a set signal to the register in response to the read control signal.

6. A data transfer circuit according to claim 1, wherein the second collision detection circuit includes
a register connected to the counter, and
a control circuit connected to the counter, the control signal outputting a reset signal to the register in response to the write control signal.

7. A data transfer circuit comprising:
a first buffer circuit storing write data in response to a write control signal and reading out data stored therein in response to a read control signal;
a counter counting a number of data stored in the first buffer circuit and outputting a count signal representing a number of the count;
a first collision detection circuit connected to the counter, the first collision circuit outputting the count signal when the read control signal indicating a reading procedure and outputting a full state signal when the read control signal indicating a waiting status; and
a second collision detection circuit connected to the counter, the second collision circuit outputting the count signal when the write control signal indicating a writing procedure and outputting an empty state signal when the write control signal indicating the waiting status.

8. A data transfer circuit according to claim 7, further comprising
a second buffer circuit connected to the first collision circuit, the second buffer circuit transferring the signal received from the first collision signal in response to a write status signal, and
a selector connected to the first buffer circuit and the second collision circuit, the selector transferring the data received from the first buffer circuit or the signal received from the second collision circuit in response to a read status signal.

9. A data transfer circuit according to claim 7, wherein the first buffer circuit is a first in first out memory.

10. A data transfer circuit according to claim 7, wherein the counter is an up-down counter having an up count input terminal connected to receive the write control signal and a down input terminal connected to receive a read control signal.

11. A data transfer circuit according to claim 7, wherein the first collision detection circuit includes
a register connected to the counter, and
a control circuit connected to the counter, the control signal outputting a set signal to the register in response to the read control signal.

12. A data transfer circuit according to claim 11, wherein the control circuit includes a delay circuit, a flip-flop circuit and a gate circuit.

13. A data transfer circuit according to claim 7, wherein the second collision detection circuit includes
a register connected to the counter, and
a control circuit connected to the counter, the control signal outputting a reset signal to the register in response to the write control signal.

14. A data transfer circuit according to claim 13, wherein the control circuit includes a delay circuit, a flip-flop circuit and a gate circuit.

15. A data transfer system comprising:
a data providing unit for providing write data and a write control signal;
a data receiving unit for receiving read data and a read control signal;
a first buffer circuit connected to the data providing unit and the data receiving unit, the first buffer circuit receiving the write data in response to the write control signal and outputting the read data stored therein in response to the read control signal;
a counter connected to the data providing unit and the data receiving unit, the counter counting a number of data stored in the first buffer circuit and outputting a count signal representing a number of the count;
a first collision detection circuit connected to the counter and the data providing unit, the first collision circuit outputting the count signal to the data providing unit when the read control signal indicating a reading procedure and outputting a full state signal when the read control signal indicating a waiting status; and
a second collision detection circuit connected to the counter and the data receiving unit, the second collision circuit outputting the count signal to the data receiving unit when the write control signal indicating a writing procedure and outputting an empty state signal when the write control signal indicating the waiting status.

16. A data transfer system according to claim 15, further comprising
a second buffer circuit connected between the data providing unit and the first collision circuit, the second buffer circuit transferring the signal from the first collision signal to the data providing unit in response to a write status signal output from the data providing system, and
a selector connected to the first buffer circuit, the second collision circuit and the data receiving unit, the selector transferring the data from the first buffer circuit or the signal from the second collision circuit to the data receiving unit in response to a read status signal output from the data receiving unit.

17. A data transfer system according to claim 15, wherein the first buffer circuit is a first in first out memory.

18. A data transfer system according to claim 15, wherein the counter is an up-down counter having an up count input terminal connected to receive the write control signal and a down input terminal connected to receive a read control signal.

19. A data transfer circuit according to claim 15, wherein the first collision detection circuit includes
a register connected to the counter, and
a control circuit connected to the counter, the control signal outputting a set signal to the register in response to the read control signal.

20. A data transfer circuit according to claim 15, wherein the second collision detection circuit includes
a register connected to the counter, and
a control circuit connected to the counter, the control signal outputting a reset signal to the register in response to the write control signal.
